(19) United States
(12) Patent Application Publication
(10) Pub. No.: US 2006/0006892 A1
(43) Pub. Date: Jan. 12, 2006

(54) Flexible test head internal interface

(76) Inventors: Roy W Green, Tabernacle, NJ (US); Charles Spear, Morgan Hill, CA (US); Victor Tejeda, Elk Grove, CA (US); Rex Cruz, San Jose, CA (US)

Correspondence Address: RATNERPRESTIA, P O BOX 980, VALLEY FORGE, PA, 19482-0980, US

(21) Appl. No.: 10/498,711

(22) PCT Filed: Dec. 11, 2002
(86) PCT No.: PCT/US02/39685

§ 371 Date: May 23, 2005

Related U.S. Application Data
(60) Provisional application No. 60/340,564, filed on Dec. 14, 2001.

(51) Int. Cl. G01R 31/02

(52) U.S. Cl. 324/755

(57) ABSTRACT

A connection module for use with a test head system is provided, the test head system including a test head for testing devices. The connection module includes a plurality of flexible circuits for transmitting and receiving signals between electronics in the test head and a device to be tested. The connection module also includes connection points on a first end of each of the flexible circuits for connecting the flexible circuits to the electronics in the test head.

### FIELD OF THE INVENTION

The present invention relates, in general, to conductive paths for use with test heads for testing electronic components, and more specifically, to flexible circuits for use with test heads.

### BACKGROUND OF THE INVENTION

An automatic test system is frequently used to test integrated circuits. Such an automatic test system may include a test head, which contains high-speed electronic circuits, which provide input stimuli signals to the device under test (“DUT”) and detect and measure the corresponding output response signals from the DUT. The test signals must be generated and processed with precision with regard to signal levels, waveforms, and temporal characteristics. In addition, the test head may contain power supplies, which provide power to the DUT and parametric test circuitry to test key electrical parameters of the DUT.

Test heads may be constructed to test a wide variety of device types including, for example, digital logic devices, memory devices, analog devices, and mixed signal devices.

Devices to be tested may have any number of electrical contacts or “pins” which connect the internal circuitry with external circuitry in an overall system. It is through these pins that the test head applies and detects test signals and/or provides power supply voltages and ground connections. In this disclosure the term “ground” is used frequently and is to be taken in its most general sense according to context and as generally understood by those skilled in the art. For example, with respect to circuits and power supplies, it refers to common returns and the point of relative zero potential, whether or not connected to earth. As another example, with respect to the transmission of test signals to and from the DUT, it refers to the return, paths of the signals, which may be individual paths as with coaxial cables or twisted pairs, shared common paths such as a common ground plane for several strip lines in a printed circuit board, or a combination of both. The return paths of signals may be connected to common points of relative zero potential, not necessarily connected to the earth, internal to the test head and/or at the DUT.

Generally, for each signal pin of the DUT, the test head must supply an individual digital, analog, or mixed signal testing circuit. Such a circuit is often called a “pin electronics” circuit, and the entire collection of pin electronics circuits is referred to as simply the pin electronics. There must be one pin electronics circuit for each device pin that is to be tested. Often test heads will contain hundreds of pin electronics circuits in order to test individual devices having hundreds of pins or several devices in parallel where each device has a fraction of the number of pins. Typically, a pin electronics circuit is designed so that it can be utilized in a variety of manners under the control of a test program. The hundreds of pin electronics circuits and other electronic components in the test head can generate considerable heat, and it is often necessary to include cooling apparatus within the test head.

The pin electronics circuits must be capable of generating and/or receiving signals that are compatible with the DUT's normal operation. Thus, today and over the next several years, pin electronics will be required to accurately generate and/or receive and process signals having frequency bandwidths of a few hundred MHz to tens or even hundreds of GHz. In addition, the timing of individual pin electronics circuits must be closely synchronized so that the timing among the signals at the DUT's pins can be controlled and analyzed. Further, the test signals must be transmitted between the pin electronics and device pins with a minimum of distortion and reflections. Thus, the test head is designed so that it can be docked with a “device handler” such as a wafer prober, die handler, or package handler, which allows each DUT to be positioned for testing at a test site that is in close proximity to the pin electronics, contained within the test head. However, there is typically a signal transmission path of several inches between a pin electronics circuit and the corresponding DUT pin. Thus, a transmission line is provided for each pin comprising a signal path and a ground path. It is generally desirable that the transmission line be implemented with a specified characteristic impedance, such as 50 or 75 ohms. Further, it is generally desirable that all of the transmission lines be of approximately the same length to minimize differences in signal delay from pin to pin to acceptable levels. Often in the prior art, coaxial cables have been used in test heads to form portions of the overall transmission lines.

The physical size and shape of the test head must be designed so that it is compatible with the handler apparatus with which it will be docked. The test head combined with the mechanical test head positioner apparatus must fit within a specified volume, which is typically less than a cubic yard. Thus, there is a limited volume available to house the pin electronics, the transmission lines, and other necessary equipment and apparatus. In many cases, it is required to have a hole of several inches in diameter through the test head to allow an operator to view the DUT as it is positioned in the test site and as it is tested. Such a viewing hole can utilize an appreciable amount of the available volume.

In addition to signals transmitted between the pin electronics and the DUT pins, special signals which are impractical or expensive to generate or monitor with the standard pin electronics may be accommodated. For example, special circuits within the test head may provide for high speed clock signals, low level radio communications signals, and others. In addition, power supply voltages and grounds are also provided. These are typically routed to the DUT by way of appropriate wiring within the test head.

Typically, electrical connections are made to the DUT by way of a probe card or a test socket mounted on a “DUT board.” If the DUT is included on a wafer and tested in a wafer prober or is on a die that has been separated from a wafer but not yet packaged and tested with a die handler, then a probe card is used. If, however, the DUT is packaged, it is tested with a package handler using a test socket mounted on a DUT board. Wafer probers, die handlers, and package handlers are referred to collectively as “device handlers.” An interface is provided between the test head and device handler apparatus to provide the connections between the test head and the probe card or DUT board when the test head is docked to the device handler apparatus. Often the interface includes compressible spring-loaded contact pins mounted on the test head that bear against conductive pads on a device interface board (“DIB”). The DIB may be the probe card or the DUT board in some instances, or it may be an intermediary board in other instances. In certain systems the DIB is mounted on the device handler apparatus; in other instances the DIB may be attached to the test head.

As an example of a prior art system, FIG. 1 is a cross-section perspective sketch (T-R Figure) illustrating a typical configuration. Test head 100 is supported by cradle (not shown), which is in turn attached to a test head positioning system or manipulator (also not shown). Docking apparatus (also not shown) as described in several patents (for example in U.S. Pat. No. 4,589,815 to Smith, U.S. Pat. Nos. 5,821,764 and 6,104,202 both to Slocum et al., and U.S. Pat. No. 5,982,182 to Chiu et al.) may be attached to the test head 100. Mounted on the test head is an interface structure. In this example the interface structure comprises contact board 130, signal contact ring 132, performance board 134, insert ring 136, and spring-loaded contact pin ring 138. Spring-loaded contact pin ring 138 holds a number of spring-loaded contact pins 140 in appropriate receptacles. In FIG. 1 test head 100 is shown in a wafer probing application; and, accordingly, spring-loaded contact pins 140 make contact with probe card 142, which has probes 144. Probes 144 make electrical contact with die 150, which is the DUT and is included on wafer 152. Wafer 152 is supported by chuck 160, which is included in the wafer prober apparatus.

Viewing hole 125 passes through the center of the test head 100, the interface structure, and the probe card 142. Thus, one can view the probes 144 and the die 150 during the testing process.

Internal to test head 100, pin electronic circuits are provided on pin cards 110 that plug into connectors 112, which are attached to pin electronics motherboard 114. It is seen that most of the volume of the test head is taken up by pin cards 110. In this example, connecting wiring 116 consisting of individual coaxial cables are used to provide signal transmission paths between the motherboard 114 and contact board 130. Although connecting wiring 116 does not directly connect to the DUT, it provides “interconnection” between the pin electronics and the DUT in that if the wiring 116 was removed, the electrical connections between the pin electronics and the DUT would be broken.

Thus, internal to test head 100 is a volume of space for pin electronics, which is deposed around viewing hole 125. A relatively small volume, which also surrounds viewing hole 125, is available for connecting wiring 116, which provides the electrical connections to contact board 130 and ultimately to spring-loaded contact pins 140. It is seen that the volume of space available for connecting wiring 116 is quite limited.

Other test heads are arranged differently. However, common features of many test heads include a viewing hole and an interface having compressible spring-loaded contact pins deposed on a ring-like structure that fits around the viewing hole. All test heads contain pin electronics circuits. In many automatic test systems other system components are located in a separate cabinet, and the cabinet is connected to the test head by means of a cable. In a few systems, the entire test system is realized within the test head. The pin electronics in many systems are implemented on pin cards that are arranged perpendicular to the DIB and which plug into a mother board that is parallel with the DIB as was described by reference to FIG. 1. The pin cards may be arranged parallel with one another in a row as shown in FIG. 1, or they may be arranged radially about a circular viewing hole. Typically such pin cards contain from one to eight pin electronic circuits. Alternatively, the pin electronics may be constructed on one or more large “pin electronic mother boards” which are arranged parallel with the DIB in a stack. Such pin electronic motherboards are typically rather large and may contain up to several hundred pin electronic circuits. Still other configurations and arrangements are feasible.

Individual coaxial cables most often provide the necessary connections between the interface and the pin electronic circuits. Other alternatives such as twisted pairs and ribbon cables have been used in low performance test systems. However, all such systems require considerable volume. Other systems have been constructed where direct mechanical connections are realized between radially arranged pin card connectors and the interface. Such systems are typically limited in pin count capacity, performance, or both.

The overall size of a test head is limited by physical constraints imposed by the range of handler apparatuses with which it will be used. Generally, as the number and complexity of pin electronic circuits and necessary connections increase, the available volume for these within a test head remains relatively constant. As the number of pin electronics circuits required in a test head grows, and the overall volume available stays relatively constant, the need for much greater wiring density is apparent. Accordingly, a means to provide many hundreds or thousands of high performance signal paths in a small volume within a test head is needed.

Further as the number of needed connections increases, the labor cost of providing individual connections as with coaxial cables increases. Also, as the number of connections increases, the chances of wiring errors and their associated costs increase as well. Accordingly, an interconnection means that can reduce the labor cost of providing accurate connections is needed as well.

Also, over the life of a test head it may become necessary to change the number or type of pin electronics circuits, their interconnections to the interface, and/or the configuration of the interface. It may be further necessary to replace certain pin electronics circuits if they experience failures. Such activities necessitate the need to disconnect and reconnect many individual interconnections and/or interface components, which can lead to considerable down time and expense. Accordingly, it would be desirable to have a way to construct an interface, and the interconnections attached to it, in a modular fashion that enables rapid installation and/or removal of prefabricated modules, each containing a number of interconnections and contacts.

### SUMMARY OF THE INVENTION

In an exemplary embodiment of the present invention, a connection module for use with a test head system is provided, the test head system including a test head for testing devices. The connection module includes a plurality of flexible circuits for transmitting and receiving signals between electronics in the test head and a device to be tested. The connection module also includes connection points on a first end of each of the flexible circuits for connecting the flexible circuits to the electronics in the test head.

### BRIEF DESCRIPTION OF THE DRAWINGS

The invention is best understood from the following detailed description when read in connection with the accompanying drawings. It is emphasized that, according to common practice, the various features of the drawings are not to scale. On the contrary, the dimensions of the various features are arbitrarily expanded or reduced for clarity. Included in the drawings are the following figures:

FIG. 1 is a partial perspective view of a prior art test head system.

FIG. 2A is an exploded perspective drawing of a test head in accordance with an exemplary embodiment of the present invention.

FIG. 2B is a perspective view of the test head in FIG. 2A from the interface side in accordance with an exemplary embodiment of the present invention.

FIG. 3A is an illustration of the arrangement of a group of contact pads on a device interface board in accordance with an exemplary embodiment of the present invention.

FIG. 3B is a plan view of a spring-loaded contact pin block with a hole pattern corresponding to the group of contact pads in FIG. 3A in accordance with an exemplary embodiment of the present invention.

FIGS. 4A and 4B are two perspective views from angles 180 degrees apart of a PE connection module in accordance with an exemplary embodiment of the present invention.

FIG. 5 is a cross sectional view of a spring-loaded contact pin block used in FIGS. 4A and 4B in accordance with an exemplary embodiment of the present invention.

FIG. 6 is a partial cross sectional view of a test head of the type shown in FIG. 2, incorporating a single pin electronics mother board in accordance with an exemplary embodiment of the present invention.

FIG. 7 is a partial cross sectional view of a test head of the type shown in FIG. 2, incorporating three pin electronics mother boards in accordance with an exemplary embodiment of the present invention.

FIG. 8 is a cross section view of two flexible circuits connecting to a pin electronics motherboard using a female connector attached to the flexible circuit and male pins attached to the motherboard in accordance with an exemplary embodiment of the present invention.

FIG. 9 is a perspective view of an individual flexible circuit assembly including connectors and stiffeners in accordance with an exemplary embodiment of the present invention.

FIG. 10A is a plan view of a flexible circuit assembly in accordance with an exemplary embodiment of the present invention.

FIG. 10B is a plan view of a flexible circuit assembly including a schematic view of the signal conductors in accordance with an exemplary embodiment of the present invention.

FIG. 10C is a plan view of a flexible circuit assembly including a schematic view of the ground/return conductors in accordance with an exemplary embodiment of the present invention.

FIG. 11 is a partial cross section of a flexible circuit taken along one of the signal conductors to show the layers of materials and adhesives in accordance with an exemplary embodiment of the present invention.

FIG. 12 is a partial cross section of a flexible circuit assembly in the region of one of the signal conductors and at right angles to the path of the conductor in accordance with an exemplary embodiment of the present invention.

FIG. 13 is a cross section view of a spring-loaded contact pin block having flexible circuits coupled to the spring-loaded contact pins by way of soldered connections in accordance with an exemplary embodiment of the present invention.

FIG. 14 is a perspective view of the pin electronics end of a flexible circuit having connector fingers for coupling with a zero insertion force connector in accordance with an exemplary embodiment of the present invention.

FIG. 15 is a cross section view of two flexible circuits connecting to a pin electronics motherboard using connector fingers on the flexible circuit and a zero insertion force connector attached to the motherboard in accordance with an exemplary embodiment of the present invention.

### DETAILED DESCRIPTION OF THE INVENTION

In another exemplary embodiment of the present invention, an interface for providing interconnection between a test head and a device to be tested is provided. The interface includes a plurality of connection modules, each of the connection modules including a plurality of flexible circuits for transmitting and receiving signals between electronics in the test head and the device to be tested. The interface also includes a device interface providing interconnection between at least one of the plurality of connection modules and the device to be tested.

In another exemplary embodiment of the present invention, a test head system is provided. The test head system includes a plurality of electronic circuits. The test head system also includes an interface for providing interconnection between the test head and a device to be tested. The test head system also includes a plurality of flexible circuits for transmitting and receiving signals between the plurality of electronic circuits and the device to be tested.

In another exemplary embodiment of the present invention, a method of connecting a test head to a device to be tested is provided. The method includes providing at least one connection module including a plurality of flexible circuits for transmitting and receiving signals between electronics in the test head and the device to be tested. The method also includes connecting the connection module between electronics in the test head and the device to be tested.

In another exemplary embodiment of the present invention, a method of modifying a test head system is provided. The method includes removing a first flexible circuit from the test head system, where the first flexible circuit has a first configuration for exchanging signals between electronics in a test head and a device to be tested. The method also includes replacing the first flexible circuit with a second flexible circuit having a second configuration, the second flexible circuit for exchanging signals between the electronics in the test head and a device to be tested. The first configuration is different from the second configuration.

In another exemplary embodiment of the present invention, another method of modifying a test head system is provided. The method includes removing a first connection module from the test head system, where the first connection module has a first configuration and includes a plurality of flexible circuits for exchanging signals between electronics in a test head and a device to be tested. The method also includes replacing the first connection module with a second connection module having a second configuration, the second connection module including a plurality of flexible circuits for exchanging signals between the electronics in the test head and a device to be tested. The first configuration is different from the second configuration.

In another exemplary embodiment of the present invention, yet another method of modifying a test head system is provided. The method includes providing a flexible circuit configured for transmitting and receiving signals between electronics in a test head and a device to be tested. The method also includes adding the flexible circuit to the test head system.

In another exemplary embodiment of the present invention, a method of assembling a test head system is provided, where the test head system includes a test head for testing devices. The method includes providing a plurality of connection modules, where each of the connection modules includes a plurality of flexible circuits for transmitting and receiving signals between electronics in the test head and the device to be tested. The method also includes assembling an interface for providing interconnection between the test head and the device to be tested, including arranging the connection modules in a predetermined configuration.

Throughout the present application there are numerous descriptions, illustrations, and discussions of spring loaded contacts or spring-loaded contact pins. An exemplary spring-loaded contact/spring-loaded contact pin is a Pogo® pin (Pogo® is a registered trade mark assigned to Delaware Capital Corp).

The present invention provides certain advantages over the prior art. First, it provides the use of flexible circuits (e.g., “flex circuits”) to substantially reduce the volume necessary to route a high number of connections between the pin electronics circuits and the interface contacts, while maintaining good transmission line characteristics for the signals exchanged between the DUT and the pin electronics. Second, it provides for subassemblies comprising a number of flexible circuits and a segment of the interface contact assembly to be prefabricated as a module; and, therefore, enables simplified assembly and maintenance of a test head. Thus, the invention saves volume within a test head while reducing manufacturing and maintenance costs.

A first aspect of the invention provides the use of one or more flexible circuits to form electrical conduction paths between pin electronics circuits and interface contacts in a test head. One flexible circuit may contain a plurality of conduction paths and thereby provide connections between a plurality of pin electronic circuits and a corresponding plurality of interface contacts. In a preferred embodiment, both signal and ground conductors are provided in one flexible circuit. The volume required for a given number of connections so implemented with a flexible circuit is substantially less than that required by the use of coaxial cable, twisted pairs, ribbon cables or the like.

In contrast to conventional conductors jacketed with an insulative material (coaxial cables, twisted pairs, ribbon cables, etc.), a flexible circuit is defined by the industry standard IPC-T-50 as a patterned arrangement of printed wiring utilizing flexible base material with or without flexible coverlayers. See “Flexible Circuit Technology,” by Joseph Fjelstad, Silicon Valley Publishers Group, 1998, page 8. Various materials have been used as the base film or substrate of a flexible circuit, for example, fluoropolymer films (e.g., DuPont Teflon), aramid fiber-based papers and cloths (e.g., DuPont Nomex), formable composites (e.g., Rogers' BEND/flexible), flexible epoxy based composites, and thermoplastic films (e.g., polyethylene, polyvinyl chloride, polyvinyl fluoride, and polyetherimide). Typically, flexible circuits are designed for manipulation in two and even three dimensions. Flexible circuits are superior to conventional conductors, for example, ribbon cable, in that flexible circuits can be used to provide a small, high speed (hundreds of megahertz and above) transmission path for testing of semiconductor components. In contrast, ribbon cable is larger, and is used for lower speed applications.

Flexible circuits are similar to printed circuit boards except that the material that they are constructed of is flexible rather than rigid. Generally, the flexible circuits are specifically designed for specific applications using well-known techniques similar to those used in printed circuit board design. The flexible circuits comprise a sandwich of alternating layers of conductive and non-conductive materials. The thickness of the flexible circuit is the combination of the individual thickness of the layers of the material plus any required adhesive or bonding material. In an exemplary embodiment of the present invention, the outer layers are constructed of insulating material. As in printed circuit board technology, individual circuit paths may be formed in conductive layers by etching away conductive material according to a predefined pattern. In an exemplary embodiment of the present invention, two layers of conductive material and three layers of non-conductive, insulating material, are utilized. (The outer two and middle layers being non-conductive or dielectric, and the other two layers conductive.) In another exemplary embodiment of the present invention, connection paths (or simply conductors) for signal connections are formed in a first one of the two conductive layers. The second conductive layer may be used for ground connections; one separate ground connection being provided under each signal connection. Alternatively, the second conductive layer can be used to form a single ground plane that is continuous under all of the signal conductors.

Thus, in an exemplary embodiment of the present invention the first conductive layer contains only signal conductors. Still further embodiments provide both signal and ground connections in the first conductive layer, which may be combined with individual ground planes or a single ground plane in the second conductive layer. For example, another exemplary embodiment of the present invention, ground conductors are included in the first conductive layer and are arranged so there is at least one ground conductor adjacent to every signal conductor. Thus, the assignment of conductors across the width of the flexible circuit is: ground, signal, signal, ground, signal, signal, ground, etc. In yet another exemplary embodiment of the present invention, each signal conductor is arranged so that it is between and adjacent to two ground conductors. Thus, the assignment of conductors across the width of the flexible circuits is: ground, signal, ground, signal, ground, etc. Yet still further embodiments allow signals and ground to be realized in both conductive layers.

A signal conductor that traverses the length of the flexible circuit may be separated from the ground plane by a non-conductive layer. Thus, a strip line type of transmission line is provided for the signal. The characteristic impedance of the transmission line is determined in part by the relative permittivity (i.e., dielectric constant) and thickness of the non-conductive layer between the signal conductor and the ground plane. It is also determined in part by the width and thickness of the signal conductor. The distance between the signal conductor and any adjacent conductors in the first conductive layer will also affect the characteristic impedance. Thus, using well-known techniques, a desired characteristic impedance in the range of approximately 28 to 75 ohms can be designed into the signal conductor transmission lines.

In an exemplary embodiment of the present invention, each flexible circuit has a length, which is several times greater than its width, and which is sufficient to reach from the pin electronics circuits to the interface contacts. As such, although the flexible circuit is not in direct contact with the device to be tested, the flexible circuit provides “interconnection” between the pin electronics and the device to be tested in that if the flexible circuit was removed, the electrical connection between the pin electronics and the device to be tested would be broken. Conductors are arranged adjacent to one another across the width of the flexible circuit so that each conductor traverses the length of the flexible circuit. The length of the flexible circuit extends between its two ends: a first end, referred to as the pin electronics end (“PE end”), providing connections between the conductors and the pin electronics circuits, and the second end, referred to as the “interface end,” providing connections between the conductors and the interface contacts.

The two ends of a flexible circuit are designed so that the ends of the conductors can be attached to their respective destinations. There are many different possibilities. In one exemplary embodiment, the conductors at the interface end terminate in conductive plated through-holes, which pass through the flexible circuit. Each interface contact is provided with a conductive post that fits closely inside a corresponding plated through-hole. The conductive posts are then all inserted into their corresponding plated through-holes, and a solder connection is made between each post and through-hole. In another exemplary embodiment, a connector block is attached to the interface end of the flexible circuit. The connector block includes a number of female receptacle contacts that are spaced so as to correspond with the spacing of a similar number of interface contacts. The connector block is attached to the flexible circuit such that each conductor in the flexible circuit is connected to one or more corresponding receptacles. Each interface contact is provided with a post that engages with a corresponding receptacle to provide both mechanical and electrical contact. Thus, the connector is inserted over the corresponding posts to form the connection between the conductors within the flexible circuit and the interface contacts. In another exemplary embodiment, male connector elements are mounted on a pin electronics module or on a motherboard, and a mating female connector is provided on the PE end of the flexible circuit. The signals and grounds provided by the pin electronics circuits are routed to individual male contacts of the male connector. The corresponding conductors contained in the flexible circuit are connected to corresponding contacts of the mating female connector. Thus, the connection between the pin electronics and the flexible circuit conductors is established by coupling the mating female connector of the flexible circuit with the male connector elements to make firm electrical connections. In yet another exemplary embodiment, a zero insertion force (“ZIF”) connector is mounted to a pin electronics module or to a mother board containing pin electronics circuits and/or modules, and a mating connector is provided on the PE end of the flexible circuit. The signals and grounds provided by the pin electronics circuits are routed to the individual contacts of the ZIF connector. The corresponding conductors contained in the flexible circuit are connected to corresponding contacts of the mating connector. Thus, the connection between the pin electronics and the flexible circuit conductors is established by inserting the mating connector of the flexible circuit into the ZIF connector and appropriately operating the ZIF connector to make firm electrical connections. In further exemplary embodiments other connection techniques as are known in the art may be used to provide connections at either end of the flexible circuit. Although the various connection mechanisms described herein (e.g., conductive posts, conductive plated receptacles, conductive tabs, ZIP connectors, etc.) are shown in connection with a given location of a given component (e.g., the interface end of a flexible circuit), it is contemplated that the connection mechanism arrangement could be reversed. As such, if a conductive post is described at a first location for mating with a conductive plated receptacle at a second location, it is clear that the conductive post may be arranged at the second location, and the conductive plated receptacle could be arranged at the first location.

The flexible circuits may be designed having a width that varies along its length. The width of individual conductors and the spacing between individual conductors are accordingly adjusted along their length to correspond to the varying width. The flexible circuit width and conductor spacing at the PE end of the flexible circuit may be designed to correspond to the dimensions of the connector apparatus that couples it to the corresponding pin electronics circuits. Similarly, the flexible circuit width and conductor spacing at the interface end may be designed to correspond to the spacing of the interface contacts to which it couples. Finally, the width of the flexible circuit may be adjusted at various places along its length to conform to specific restrictions imposed by the physical design and layout of the test head. For example, the flexible circuit width may be reduced at points where it has to pass through a narrow opening.

In another exemplary embodiment of the present invention, a PE connection module is provided comprising a segment of an interface assembly combined with a plurality of flexible circuits. In test heads where the interface assembly is designed as a ring that surrounds a viewing hole through the test head, the segment of the interface assembly may, for example, be a quadrant, sextant, or octant of the interface assembly. Thus, the PE connection module provides flexible circuit connection for all of the pin electronics circuits and grounds that connect to the DUT through the interface assembly segment. The interface assembly segment includes the electrical contacts that provide the connection to the DIB, for example spring-loaded contact pins, together with the apparatus that holds them and the apparatus which enables them to be connected to the flexible circuits.

In another exemplary embodiment of the present invention, a block made of insulating material is provided, which has rows of holes bored through it. Spring-loaded contact pin receptacles are fitted into the holes, and spring-loaded contact pins are inserted into these receptacles from a first side of the block. The spring-loaded contact pin receptacles are conductive and have conductive posts, which are preferably square in cross section, attached to them and which extend through the second side of the block. Two adjacent rows of holes correspond to all of the connections provided in the two conductive layers of one flexible circuit. For every flexible circuit, there are two rows of holes in the block. The flexible circuits are connected to the posts by techniques as previously described. The lengths of the flexible circuits are designed so that the electrical path for each signal will be approximately the same. Thus, certain flexible circuits may be longer or shorter than others. Also, the physical distance within the test head over which each flexible circuit will traverse will vary from flexible circuit to flexible circuit. Accordingly, each flexible circuit may be folded across its length as is required to fit. The PE ends of each flexible circuit are provided with appropriate connection features to allow it to be connected to its respective pin electronics circuits. The module thus constructed is preformed so that it conveniently fits into place in the test head without appreciable adjustment.

In another exemplary embodiment of the present invention, a method for assembling a PE connection module is provided that includes the steps of providing the necessary elements as described above in addition to providing appropriate assembly fixtures.

In another exemplary embodiment of the present invention, a method of assembling a test head is provided which includes the steps of providing PE connection modules, connecting each PE connection module to its corresponding pin electronics circuits, and attaching its interface segment to the test head.

In another exemplary embodiment of the present invention, a method of changing the number of pin electronics circuits and interconnections within a test head is provided which includes the steps of removing one or more selected PE connection modules and replacing it or them with PE connection modules having the new configuration of interconnections that is needed.

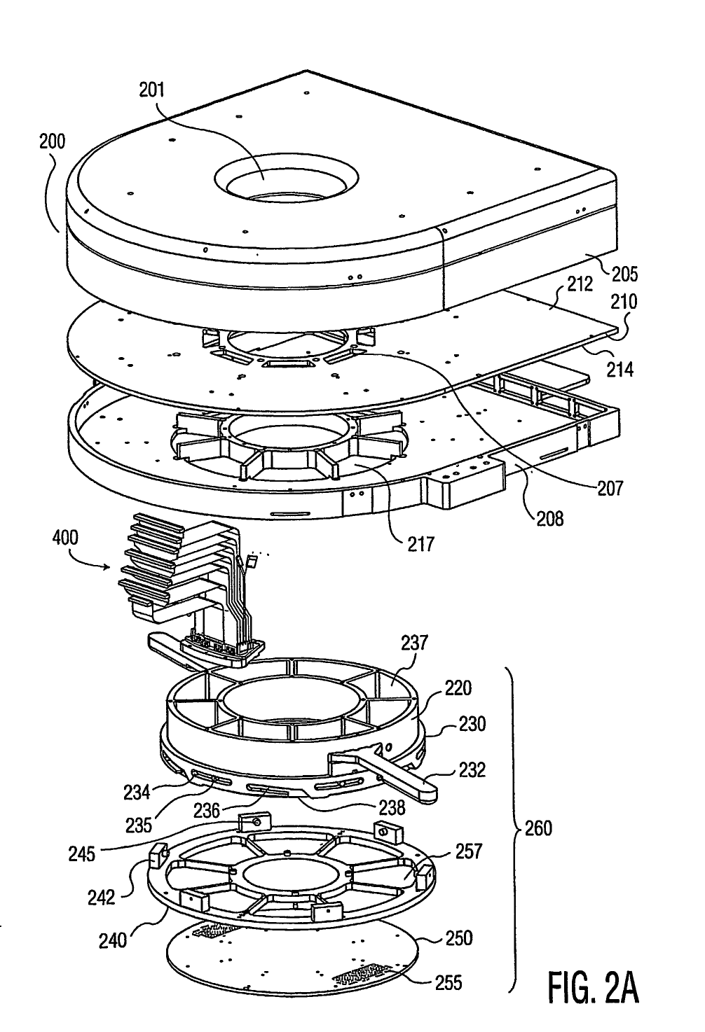

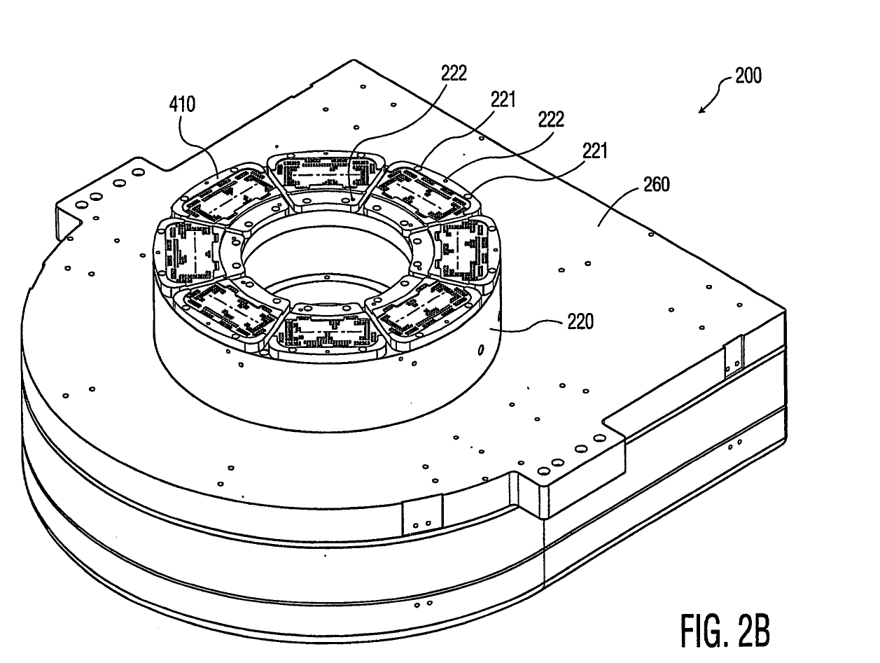

FIG. 2A shows an exploded perspective view of a contemporary test head 200 including cover unit 205, pin electronics mother board 210, test head housing 208, interface unit 260, and device interface board (DIB) 250. Interface unit 260 includes interface housing 220, compression ring 230, DIB holder 240, handles 232, and associated items. DIB 250 could either be a DUT board with a test socket for testing packaged devices or a probe card including probes for testing devices on a wafer or unpackaged die. Test head 200 also includes eight pin electronic connection modules (“PECM”) 400; however, only one PECM 400 is shown in FIG. 2A for clarity. Test heads may be designed to accommodate either more or fewer than eight PECM's. Test head 200 also includes viewing hole 201, which passes through cover 205, motherboard 210, housing 208, and interface unit 260. DIB 250 may or may not include the viewing hole; usually viewing holes will pass through a probe card but not a DUT board.

FIG. 2B is a perspective view of test head 200 including interface unit 260. For clarity, compression ring 230, DIB holder 240, handles 232, DIB 250 and associated items are not included. Each PECM 400 includes spring-loaded contact pin block 410, which holds spring-loaded contact pins 505. Eight spring-loaded contact pin blocks 410, one for each PECM 400, are shown attached to interface housing 220 with screws 221. Guide pins 222 are used to precisely align each spring-loaded contact pin block 410 in its proper position.

Returning to FIG. 2A, DIB 250 is of conventional type and includes electrically conductive circuit paths (not shown) for conveying signals, power, grounds, and the like to and from the DUT. The circuit paths may be designed and fabricated in well-known ways consistent with printed circuit board technology. The circuit paths terminate at contact pads 255 which are arranged in groups around the periphery of the DIB 250, as is conventional practice. For simplicity, only two groups of contact pads 255 are shown in FIG. 2A; however, one group of contact pads 255 corresponding to each PECM 400 is preferably included, providing a total of eight groups in the present exemplary embodiment.

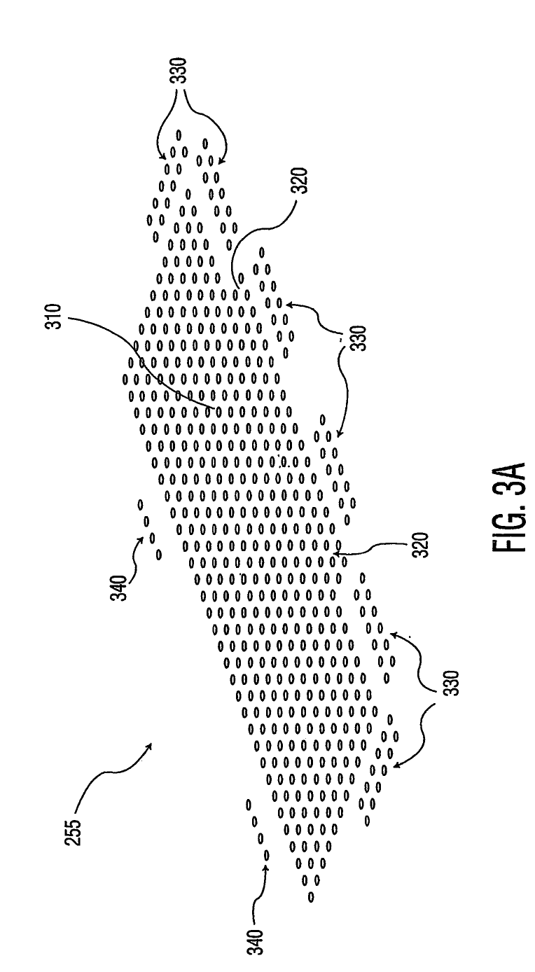

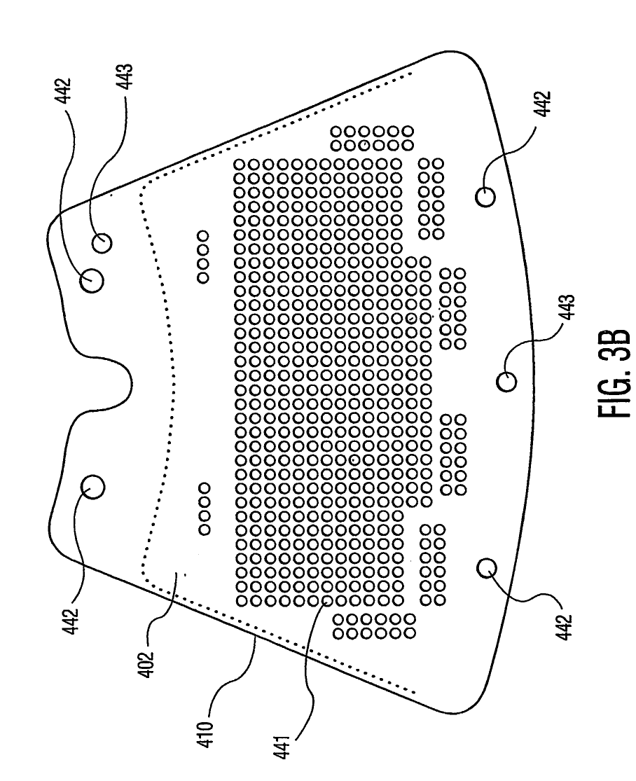

To provide more detail, FIG. 3A is a closer view of an example of a single group of contact pads 255 on a DIB 250 (not shown). There are a total of 500 contact pads in the group shown. Twelve parallel rows 310 of 32 contact pads each, provide 384 contact pads. These are utilized to provide 192 signal-ground connection pairs between the DUT and the pin electronics. The contact pads are spaced on 100 mil centers along each row, and the rows are spaced 100 mils apart, center-to-center. Thus, a rectangular array having 12 rows by 32 columns of contact pads on a 100 mil grid is provided. Signals and grounds alternate along any row and along any column forming a checkerboard pattern. This is in accordance with conventional practice in the field, and the spacing is compatible with a wide range of standard connector products.

Two parallel rows 320 of 18 contact pads, providing 36 contact pads. These are used to provide utility and/or low frequency signals to DIB 250 (not shown). The contact pads are spaced on 100 mil centers along each row, and the rows are spaced 100 mils apart, center-to-center. The assignment of signals and grounds is not critical and may vary from one contact pad group 255 to another. For convenience, the rows are arranged parallel with the 12 rows 310. Six sets 330 of two parallel rows of six contact pads each, providing 72 contact pads. These are used to provide power supply voltages and grounds to the DUT. Also special high level test signals may be provided through these contact pads. A 100 mil spacing between contact pads is utilized for compatibility with standard connectors. Two sets 340 of four contact pads, providing 8 contact pads. These are utilized to provide special test signal to the DUT such as clocks and low-level communications signals which must be conveyed to DIB 250 by means of coaxial cable. A 100 mil spacing between contact pads is utilized for compatibility with standard connectors.

Thus one group of contact pads 255 provides connections for up to 192 signals and their grounds and a variety of power supply voltages and grounds, utility signals, clocks, and other special signals. Clearly, groups of contact pads 255 may have either fewer or more contact pads and may be arranged in any number of patterns different than shown in this example, as might be necessary to accommodate other test system specific requirements. In the embodiment described herein, eight PECMs 400 and corresponding groups of contacts 255 are used; each PECM 400 and group of contacts 255 provides an octant of the total “ring interface” which encircles viewing hole 201. Other configurations are possible, for example, four or six PECMs and contact groups forming sextants and quadrants respectively of a ring interface. Although ring interfaces are normally the most practical and offer many advantages, the invention may be used in configurations which are not rings.

Returning again to FIG. 2A, DIB 250 is secured to DIB holder 240, typically with screws (not shown). DIB holder 240 includes cut outs 257. Each group of contact pads 255 is aligned with a cut out 257 so that each contact pad 255 is accessible through its corresponding cut out 257. In the embodiment illustrated, eight cut outs 257 are provided; and, correspondingly, eight groups of contact pads 255 may be accommodated. Clearly, a system may be designed with either more or fewer cutouts 257 and groups of contact pads 255.

Spring-loaded contact pin block 410, illustrated in the plan view in FIG. 3B, is sized and shaped so that it fits closely within DIB cut outs 257. Spring-loaded contact pin block 410 has an upper surface 402 and a lower surface 404 (not shown). Holes, for example 441, are bored through spring-loaded contact pin block 410 according to the pattern of the corresponding group of contact pads 255 on DIB 250. Four holes 442 are included for screws 221 which attach it to DIB 250. Also included are two alignment pin holes 443, which receive alignment pins 222 that align the block with respect to DIB 250.

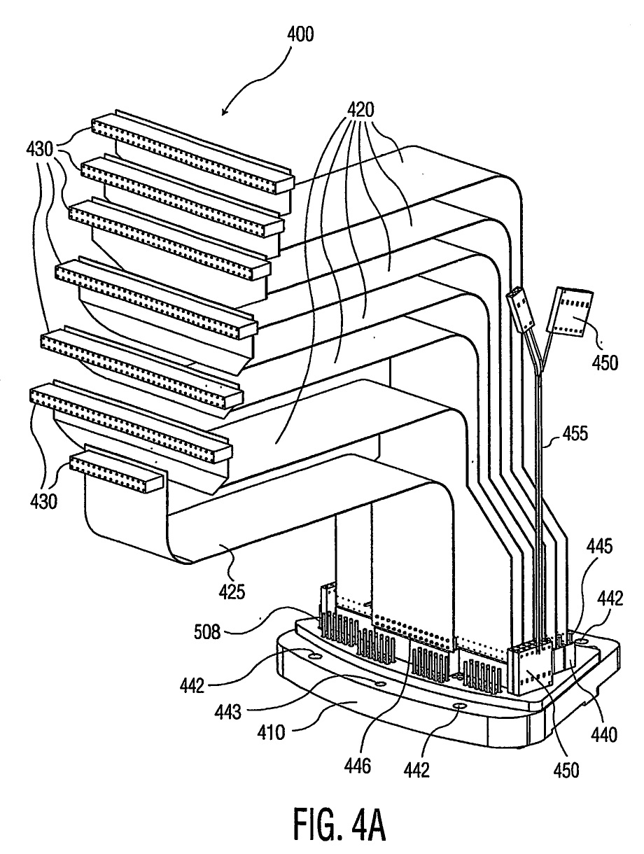

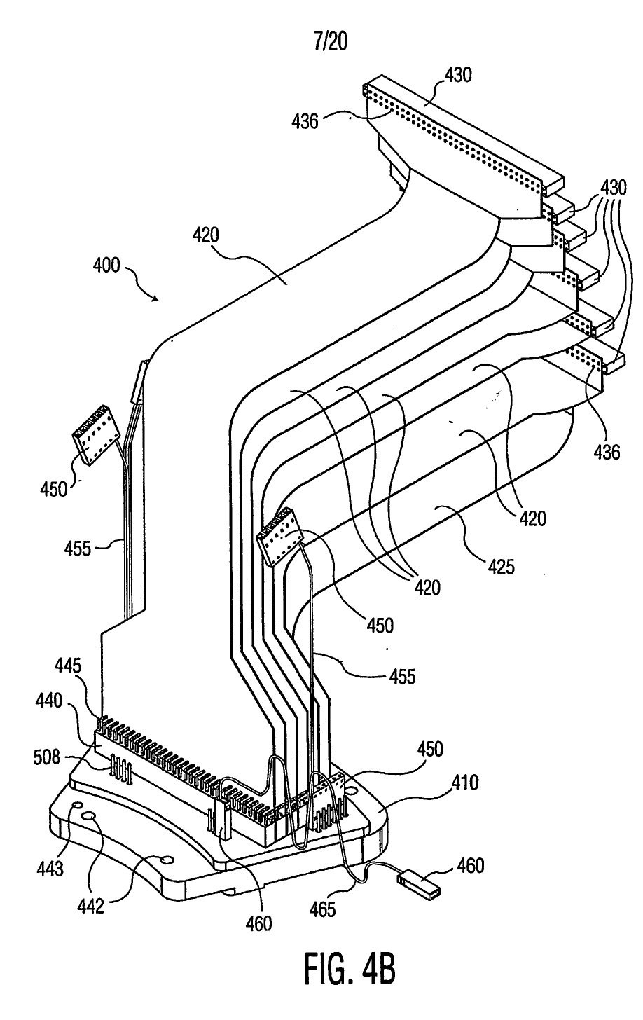

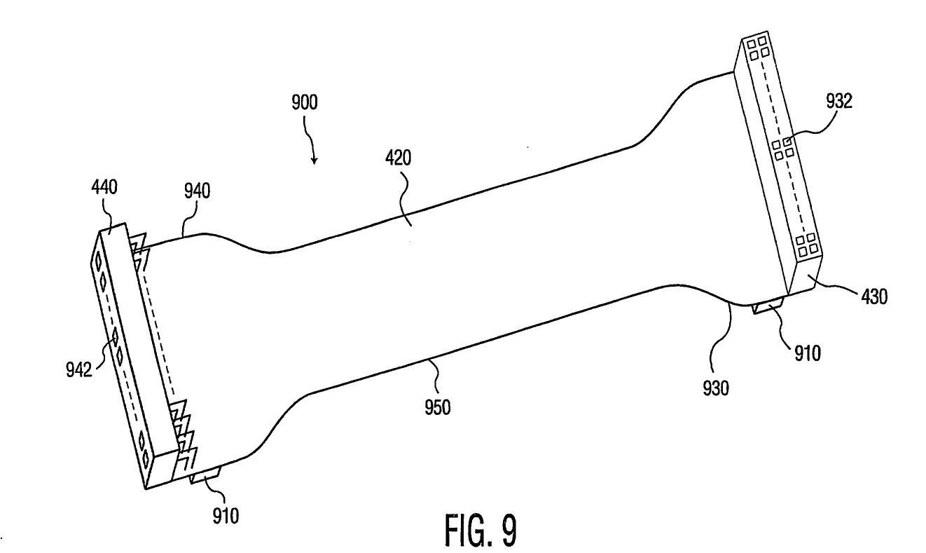

PECM 400 is shown in more detail in the perspective views provided by FIGS. 4A and 4B. PECM 400 includes signal flexible circuits 420, auxiliary flexible circuit 425, female connectors 430, right angle female connectors 440, and spring-loaded contact pin block 410. Also included are additional wires 455, coaxial cables 465, connector units 450, and coaxial connector units 460. An assembly, comprising a signal flexible circuit 420, female connector 430 and a right angle female connector 440, will be referred to as a signal flexible circuit assembly 900 (See FIG. 9). Connectors 430 have pins (not visible), which serve to attach connectors 430 to their respective flexible circuits 420 and 425. Connectors 440 have right angle pins 445 which attach them to their respective flexible circuits 420 and 425. The pins extend through holes in flexible circuits 420 and 425 and are soldered in place with solder joints 436 and 446. Generally, each signal flexible circuit assembly 900 is used to connect a plurality of signals and signal ground references between the pin electronics and the DUT. In a preferred embodiment, each flexible circuit 420 provides connections for 32 signals and their grounds, which ultimately connect with two of the 12 rows 310 of 32 contact pads 255. Further details of a flexible circuit assembly 900 are provided later.

Auxiliary flexible circuit 425 is used to connect a plurality of “utility” and low frequency signals to the DIB 250 and/or DUT by means of the two rows 320 of 18 contacts pads 255. For example, signals to control specialized test functions incorporated in the DIB 250 or low speed configuration control signals to the DUT. The additional wires 455 are used to conduct power and power ground returns to the DUT and also to provide connections for any signal of a power level too high to be conducted by flexible circuitry. The coaxial cables 465 are used to conduct any signals such as clocks and low-level communications signals that require such special treatment.

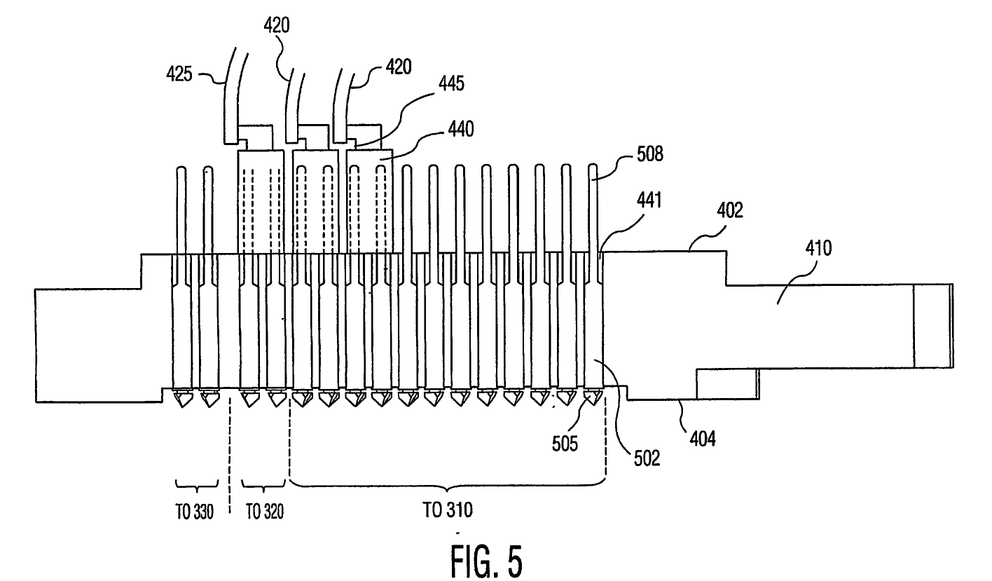

It is desirable in an automatic test system to be able to easily change DIBs, because different devices to be tested each have their own unique interface requirements. Also DIBs are subject to wear and tear and must be replaced from time to time on systems dedicated to testing just one type of device. Accordingly, the DIB holder 240 attaches to interface housing 220 in a manner that is typical of contemporary industry practice and which facilitates quick and easy changeover, as shown in FIG. 2A. To achieve this, compression ring 230 is attached in a rotatable manner to interface housing 220. In particular, compression ring 230 has slots 234 that are perpendicular to the axis of rotation. Cam followers 235 are attached to interface housing 220, and they project through slots 234. Thus, compression ring 230 can rotate through an angle defined by the length of slots 234 minus the diameter of cam followers 235. Handles 232 are attached to compression ring 230 to enable an operator to rotate compression ring 230 with respect to interface housing 220. Disposed between slots 234, are inclined slots 236 which have an opening 238 to the outer edge of compression ring 230, which faces DIB holder 240. Cam followers 245 are attached to cam follower mounting blocks 242 which are in turn attached to DIB holder 240. Cam followers 245 are positioned so that they each can enter a corresponding opening 238 in compression ring 230 simultaneously. When each cam follower 245 is seated in its opening 238, each spring-loaded contact pin body 410 will be just entering its respective cut out 257, providing alignment between contact areas 255 on DIB 250 and spring-loaded contact pins 505 (shown in FIG. 5). Handles 232 may now be turned by an operator, and cam followers 245 will follow inclined slots 236, drawing DIB holder 240 and its attached DIB 250 into contact with spring-loaded contact pins 505. It is noted that DIB 250 must be carefully aligned with and rigidly attached to DIB holder 240. This may be accomplished with conventional means such as alignment pins and screws. As the DIB 240 is drawn into contact with the spring-loaded contact pins 505, considerable force is exerted as the spring-loaded contact pins 505 are compressed. Typically, each spring-loaded contact pin 505 will exert a force in the neighborhood of two ounces when compressed. This force is necessary to ensure a low resistance connection between the spring-loaded contact pin 505 and its corresponding contact pad 255 on the DIB 250. As there are hundreds or thousands of spring-loaded contact pins 505 in a typical system, the total force can be considerable. For example, in the embodiment described herein there can be as many as 4000 spring-loaded contact pins 505 resulting in an approximate compression force of 500 pounds.

Referring now to FIG. 5, which is a cross sectional view of spring-loaded contact pin block 410, spring-loaded contact pin receptacles 502 are press fitted into the holes 441. A spring loaded spring-loaded contact pin 505 may be inserted in each receptacle 502. In particular, a spring-loaded contact pin 505 will be placed in each receptacle where it is desired to make an electrical connection between the test head 100 circuitry and DIB 250. Each spring-loaded contact pin 505 is inserted so that its contact point projects below lower surface 404. Thus, spring-loaded contact pin 505 is able to make contact with its corresponding contact pad 255 (not shown). Each spring-loaded contact pin 505 is electrically connected to its respective spring-loaded contact pin receptacle 502. Each spring-loaded contact pin receptacle 502 has a conductive post 508 (also illustrated in FIG. 4B) coaxially attached to it such that the post 508 projects from upper surface 402 and is perpendicular to upper surface 402. Each post 508 is electrically connected to its respective spring-loaded contact pin receptacle 502 and spring-loaded contact pin 505, if included. The combination of receptacle 502, spring-loaded contact pin 505, and post 508, will be referred to as a “spring-loaded contact pin assembly.” In an exemplary embodiment, the posts 508 are square in cross section and are 0.025 inches on a side (so called 0.025 square post), which are commonly used for wire wrap and solder connections as well as male contacts for mating with suitable female connector elements.

Connectors 440, 450 and 460 attached to flexible circuits 420 and 425, wires 455, and coaxial cables 465 (not shown in FIG. 5, See FIGS. 4A and 4B) may be plugged onto posts 508 at appropriate locations. For example, FIG. 5 shows three right angle female connectors 440 plugged on to six rows of spring-loaded contact pin posts 508. Each connector 440 spans two rows of spring-loaded contact pin posts 508. Two of the connectors 440 are attached to signal flexible circuits 420 and are plugged onto four adjacent rows of spring-loaded contact pin posts 508. These four rows correspond in location to four adjacent rows in the 12 rows 310 of 32 contact pads 255 for signal-ground connection pairs. The other connector 440 is attached to auxiliary flexible circuit 425 and plugs onto the two rows 320 of 18 contact pads 255 for utility and/or low frequency signals.

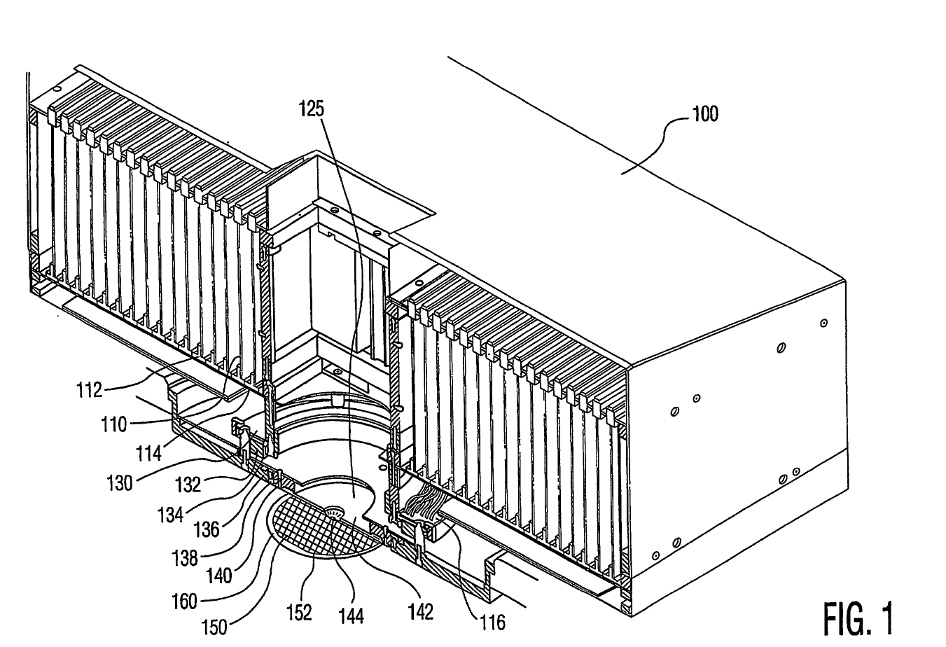

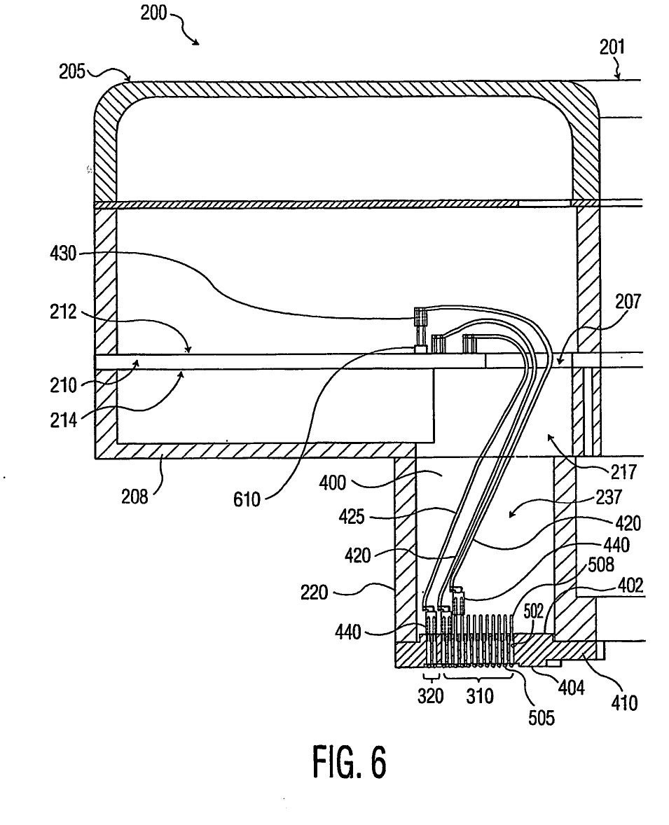

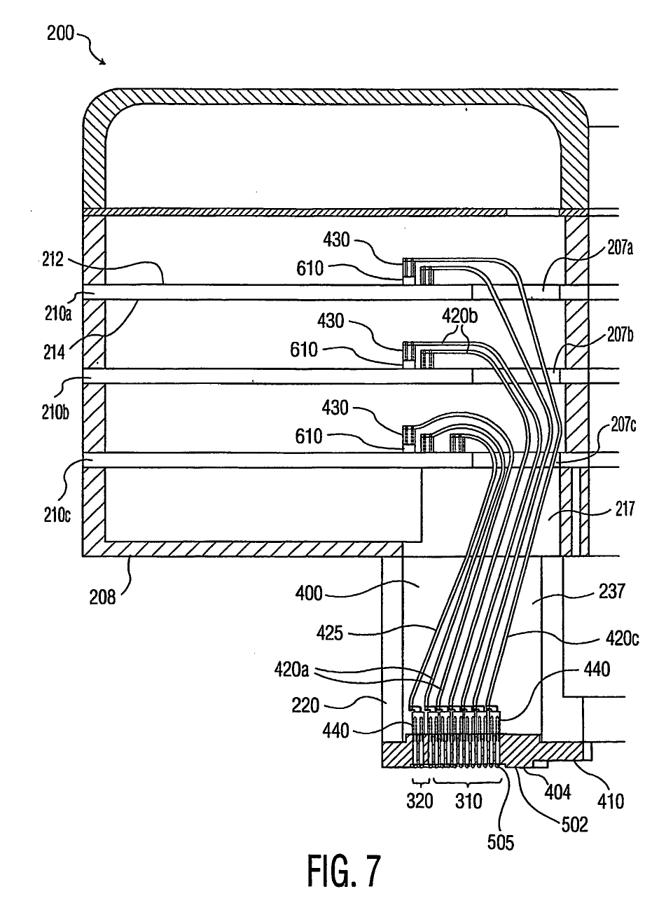

FIG. 6 is a partial cross section of the test head 200 assembly comprising cover 205, body 208, motherboard 210, interface housing 220, and PECM 400. Motherboard 210 includes an upper side 212 and a lower side 214, and it contains pin electronics circuitry (not shown). The pin electronics circuitry may be mounted directly on motherboard 210, or it may be mounted on daughter boards (not shown or similar to those shown in FIG. 1), which are mounted in turn on motherboard 210. It is possible for the pin electronics circuitry to be partially mounted on motherboard 210 and partially mounted on daughter boards. Usually pin electronics circuitry is mounted on the upper side 212. This allows access to the pin electronics for trouble shooting or other purposes by simply removing cover unit 205. In still other configurations it would be possible to utilize two or more motherboards arranged parallel to one another; however, for simplicity, FIGS. 2 and 6 show only one motherboard 210. FIG. 7, however, provides a partial cross sectional view of a test head 200 having three motherboards 210a, 210b, and 210c. Motherboard 210 includes slots 207. The purpose of slots 207 is to allow the passage of connecting wiring between the upper surface of motherboard 210 and spring-loaded contact pin receptacles 502. In the present invention, flexible circuits 420 and 425 provide this connecting wiring.

Interface housing 220 is attached to test head housing 208 using conventional techniques (not shown). Interface housing 220 has a number of channels corresponding to the number of contact pad groups 255 and PECMs 400. Interface housing 220 is attached to test head body 208 in such a manner that openings 217 are aligned with channels 237 and slots 207.

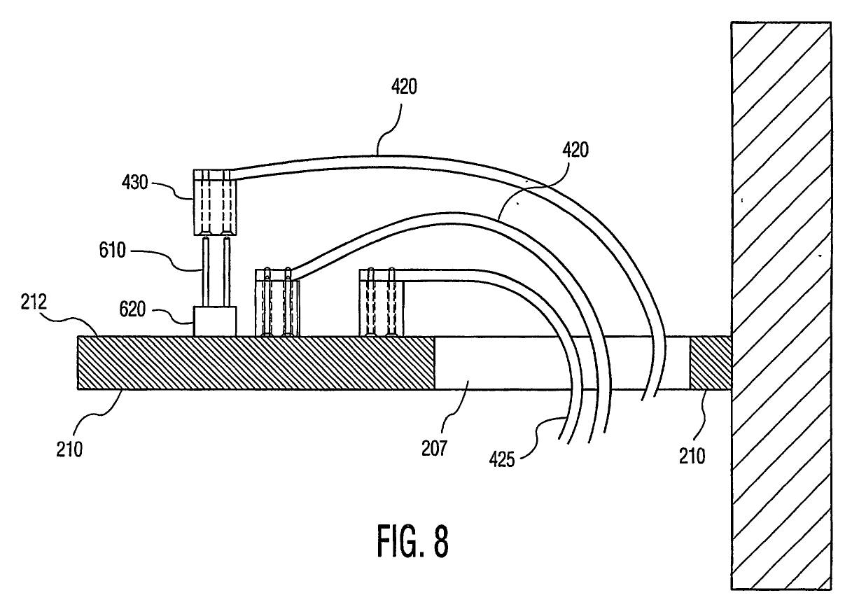

Spring-loaded contact pin block 410 is aligned with and attached to interface housing 220 using conventional means such as alignment pins 222 and screws 221 (Not shown in FIG. 6, see FIG. 2B). Two flexible circuits 420 as well as flexible circuit 425 are connected to spring-loaded contact pins mounted in block 410 as was described with respect to FIG. 5 (which is an enlarged and more detailed view of the spring-loaded contact pin block 410 and associated hardware in FIG. 6). The flexible circuits 420 and 425 extend through channel 237, opening 217, and slot 207 to the upper side 212 of motherboard 210, where female connectors 430 are plugged onto corresponding male connections 610, which are in turn connected to pin electronics circuitry (not shown). FIG. 8 provides an enlarged view of the connections with motherboard 210. Spacer 620 is provided to elevate one set of male connections 610 somewhat higher than its neighbors to allow the two connectors 430 to be positioned closely adjacent to one another without undo interference between their corresponding flexible circuits 420.

In the embodiment under consideration, the pin electronics motherboard 210 provides pin electronics circuitry for a total of 512 signal-ground pairs, and there are a total of eight PECMs 400. The pin electronics circuitry is normally disposed uniformly about viewing hole 201. Each flexible circuit 420 is configured, as previously described, to accommodate 32 signal-ground pairs. The signal ground pairs are distributed uniformly among eight PECMs 400, which are disposed uniformly about viewing hole 201. Thus, each PECM is configured with two flexible circuits 420 as shown in FIG. 6, so that each PECM 400 handles 64 signal-ground pairs. Additionally, each PECM may include a variety of other signals, power supply voltages, power grounds, etc. as has been discussed. Thus, the full potential capacity of each PECM 400 and corresponding groups of contacts 255 on DIB 250 has not been utilized in the described embodiment. (Note, for simplicity in FIG. 6, spring-loaded contact pin positions corresponding to contact pad sets 330 and 340 are not shown. Also the spring-loaded contact pin positions are not to scale)

To increase the pin electronics capacity of the test head, additional pin electronics motherboards 210 may be added. FIG. 7 is a partial cross section of a system having three pin electronics motherboards 210a, 210b, and 210c. Each motherboard includes pin electronics circuits for 512 signal-ground pairs for a total of 1,536. Each one of the eight PECMs 400 includes all six signal-flexible circuits 420. Again, each flexible circuit 420 handles 32 signal-ground pairs, so each PECM 400 accommodates 192 signal-ground pairs, or one-eighth of the total 1,536.

Referring again to FIG. 7, motherboards 210a, b and c are mounted parallel with one another in test head 200 and such that their slots 207a, 207b, and 207c are all aligned with respective openings 217 and channels 237. The flexible circuits 420a, 420b, and 420c are then all routed through the passages thus formed to their respective motherboards. In particular the pairs flexible circuits 420c that are the closest to the center of test head 200 are led through the slots of all three motherboards 210a, b, and c and are connected to the uppermost motherboard 210c. The center pair of flexible circuits 420b are led through only the lower two motherboards 210a and b, and are connected to motherboard 210b. Finally, the outmost pairs of flexible circuits 420a are led only through the lowest motherboard 210a to which they are connected.

It is desirable to make slot 207 as small as possible in order to maximize the real estate available on motherboard 210 for circuitry. The use of flexible circuits 420 substantially reduces the area necessary for slot 207 in comparison to prior art techniques, which typically use bundles of coaxial cables, twisted pairs, or ribbon cables.

Flexible circuit technology and design know how have been in existence and well known for many years, and typical design and manufacturing practices are used in embodiments of the present invention. Here, we summarize some of the key aspects of the flexible circuits used in a preferred embodiment.

Flexible circuits are available from a number of sources including for example, World Circuit Technology, Inc. in Sun Valley, Calif., Flexible Circuit Technologies in Saint Paul, Minn., and Advanced Flexible Circuits, Inc. in Minneapolis, Minn. A trade journal, “Flexible Circuitry & Electronic Packaging” is dedicated to the technology. The article, “Comparison of Printed Flexible Circuitry and Traditional Cabling,” by Jack Lexin, in InterConnection Technology, December 1992, provides an overview of the technology. Flexible circuits are typically custom designed for every application by well known techniques, which are similar to printed circuit design techniques. Aspects of the design of signal flexible circuits 420 and signal flexible circuit assemblies 900 are described in the following.

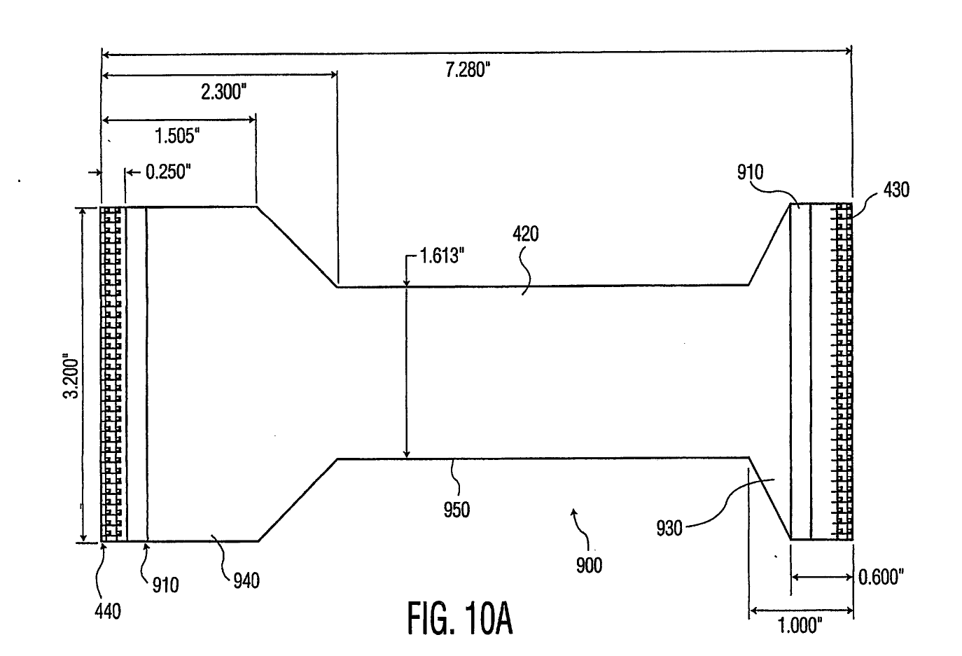

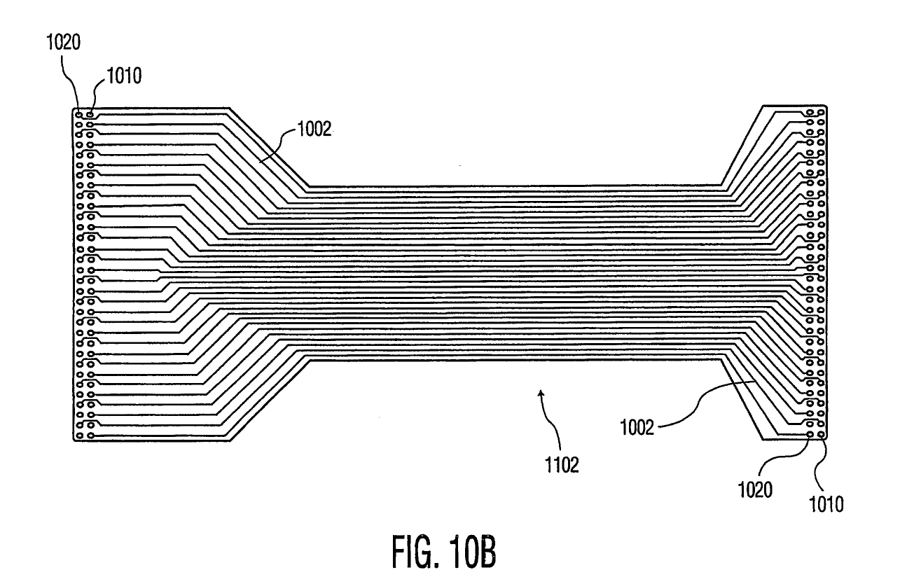

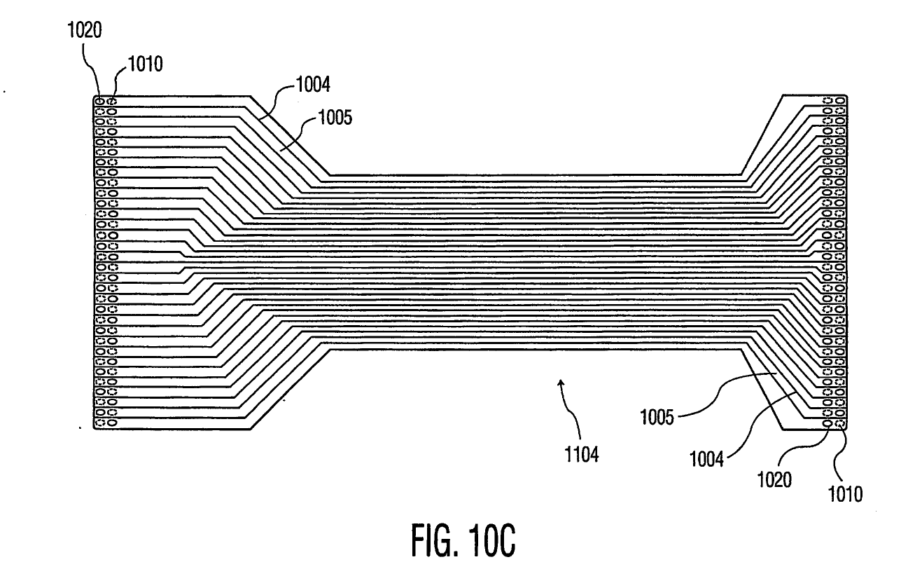

Recall that FIGS. 4A and 4B included signal flexible circuits 420 and auxiliary flexible circuits 425. FIG. 9 is a perspective sketch and FIG. 10A is a plan view of one of the signal flexible circuit assemblies 900, including signal flexible circuit 420, used in a preferred embodiment of the invention. In this preferred embodiment this flexible circuit assembly 900 provides connections for 32 signals and their ground references between the pin electronics and the DUT. The flexible circuit assembly 900 has two ends: the interface end 940 and the PE end 930. Stiffener 910 is attached to the flexible circuit near the PE end 930 and the Interface end 940 to provide some local rigidity Female connector 440 is provided at interface end 940, and it provides 64 receptacles in two rows of 32 receptacles 942 each. The spacing between receptacles 942 is chosen to correspond to the spacing between contact pads 255 in two adjacent rows 310 of 32 contact pads as shown in FIG. 2A. In the embodiment being described, receptacles 942 are spaced on 100 mil centers along a row, and the two rows are spaced 100 mils apart center-to-center. Each receptacle 942 is of a type that is designed to mate with posts 508, which are attached to spring-loaded contact receptacles 502. Thus, connector 440 provides simultaneous connection with two adjacent rows 310 of the 12 rows 310 of 32 contact pads. Similarly, female connector 430 is provided at PE end 930, and it also provides 64 receptacles 932 in two rows of 32 receptacles each. Mating male connector elements may be included on PE motherboard 210 to provide connections with appropriate pin electronics circuits. In the embodiment being described, receptacles 932 are also located on 100 mil centers along a row and from one row to the other. Connectors 430 and 440 are standard products that are commercially available Connectors 430 and 440 are attached to flexible circuit 420 by way of contact pins (not visible), which extend from each of the receptacles 932 and 942. The contact pins extend through plated-through holes or vias 1010 and 1020 (not visible in FIG. 9) and are soldered in place. The contact pins of connector 430 are straight so that the axes of the receptacles 930 are perpendicular to the surface of flexible circuit 420. The contact pins 445 of connector 420 have right angle bends so the axes of receptacles 940 are parallel with the surface of flexible circuit 420.

Flexible circuit assembly 900 has an overall length of approximately 7¼ inches. The width of flexible circuit 420 varies along its length. The width at both ends in the embodiment being described is approximately 3¼ inches. However, the width is narrowed to approximately 1⅝ inches along the central portion 950 of the length. This narrowed width facilitates the placement of the flexible circuit in channel 237, opening 217, and slot 207.

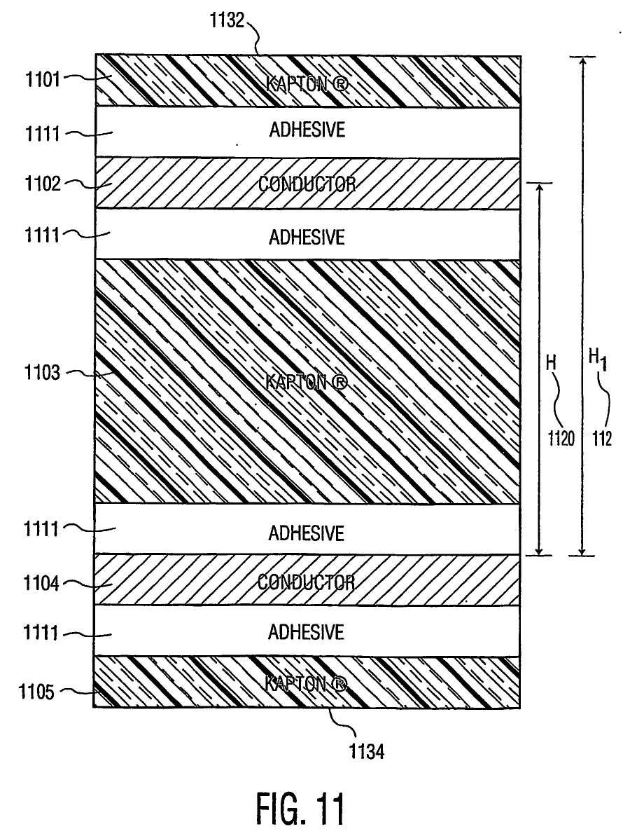

The flexible circuit 420 is constructed in a conventional fashion as a multilayer structure of conductors and dielectrics. FIG. 11 is a schematic representation of a cross section of flexible circuit 420, which includes two layers 1102 and 1104 of conductive material such as copper and three layers 1101, 1103 and 1105 of dielectric material such as Kapton® (registered trademark of E.I. DuPont de Nemours and Co., Corp., Wilmington, Del.), arranged in a five layer sandwich. Conductive patterns may be etched in conductive layers 1102 and 1104. The layers are adhered to one another with an appropriate adhesive 1111. The individual layers are preferably very thin, having a typical thickness of 1 to 5 mils. The thickness of the adhesive is also approximately 1 mil. Accordingly, the adhesive layers 1111 are significant in the overall structure, and the adhesive 1111 constitutes a significant portion of the overall thickness of the flexible circuit. In the embodiment being described, the conductors in both layers 1102 and 1104 are derived from copper sheet weighing 1 ounce per square foot; this provides a thickness in both layers of approximately 1.2 mils each after the patterns have been etched in them. The outer two layers 1101 and 1105 are of Kapton® and are each 1 mil thick. The central layer 1103 is also of Kapton® and is 5 mils thick. The layers of adhesive 1111 between layers dielectric layers 1101, 1103, and 1105 and conductive layers 1102 and 1104 are nominally 1 mil thick Thus, the overall thickness of the flexible circuit is nominally 13.4 mils.

Individual conductors are formed in the conductive layers 1102 and 1104 by etching away conductive material according to a predefined pattern. In the present embodiment, and as described in more detail in the following, layer 1102 is used to conduct 32 signals; and layer 1104 is used to provide 32 individual ground planes, one for each signal.

FIG. 10B is a representation of a plan view of layer 1102. Thirty-two conductive traces 1002 are provided to convey signal between the two ends of flexible circuit 420. In the embodiment under discussion, the width of each trace is approximately 5.5 mils. Two rows of 32 plated through-holes 1010 and 1020 are provided at each end of flexible circuit 420 to receive the connection pins of connectors 430 and 440 as previously described. These plated-through holes 1010 and 1020 pass through all layers of flexible circuit 420, and they are all plated with conductive material, such as copper or an appropriate alloy as conventionally practiced. Each end of each conductive trace 1002 connects to a single through hole 1020 at each end of flexible circuit 420.

Connectors 430 and 440 are assembled to flexible circuit 420 by inserting their contact pins into plated through holes 1010 and 1020 respectively. Each contact pin is then soldered in place. Thusly, continuity is established between respective receptacles 932 and 942 or both connectors 430 and 440.

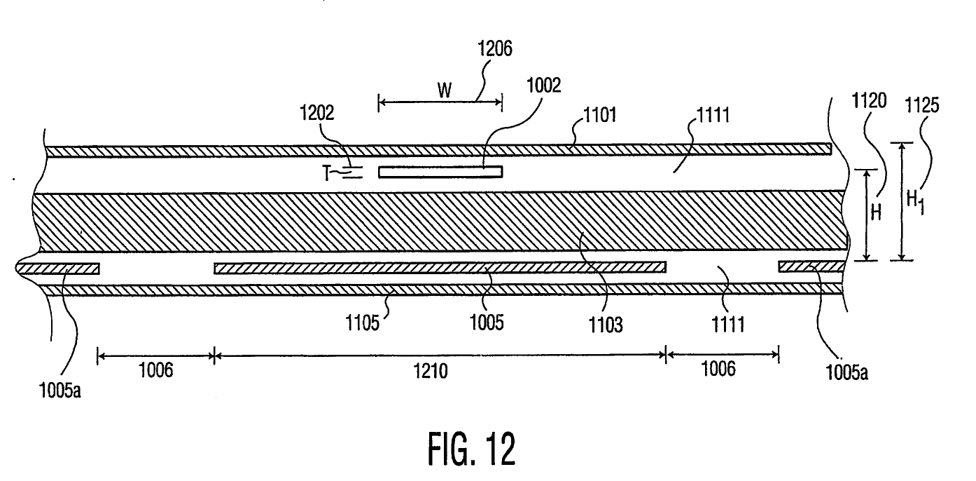

FIG. 10C is a representation of a plan view of layer 1104. The interpretation of FIG. 10C is different from that of FIG. 10B. That is, in FIG. 10C, the lines 1004 between the ends of flexible circuit 420 represent areas where conductive material has been removed, providing separations between conductive regions 1005. At each end of flexible circuit 420 the end of each conductive region 1005 is connected to its corresponding plated through hole 1010 and is insulated from plated through hole 1020. Continuity of ground is therefore established between respective receptacles 932 and 942 or both connectors 430 and 440. Thus, each conductive region 1005 forms a ground plane conductor parallel with a respective signal trace 1002 in layer 1102. FIG. 12 provides a cross sectional view of flexible circuit 420 in the vicinity of one signal conductor 1002—ground plane 1005 pair. In other embodiments it is possible to have a single ground plane conductor in layer 1104 which extends across the entire width of flexible circuit 420. However, it is found that separating the grounds into individual regions provides greater mechanical flexibleibility in flexible circuit 420, which is important in the installation of a PE connection module 400 and maintenance of the test head 200. Also, in certain testing situations, it may prove beneficial to have a separate reference for each signal. The separated configuration may also facilitate differential pairs, current loops and the like; in such configurations the separate region on layer 1104 would be used to provide a signal return path which may be different from ground, while other regions could be used for grounds as might be required.

The flexible circuit is furthermore designed to provide a controlled characteristic impedance of the signal conductors and to have reasonably low cross talk between adjacent signal conductors. The process of designing flexible circuitry to provide a desired characteristic impedance is well known and has been practiced for many years. For example, certain publications of the IPC-Association Connecting Electronics (formerly the Institute for Interconnecting and Packaging Electronics), Northbrook, Ill., provide guidance. One such publication is No. D-317A, “Design Guidelines for Electronic Packaging Utilizing High Speed Techniques.” The article “Embedded Microstrip Impedance Formula” by D. Brooks, appearing in Printed Circuit Design, a Miller Freeman publication, February, 2000, provides commentary on the IPC Association Connecting Electronics' publications and offers certain modifications to their formulae. Following Brooks, the characteristic impedance of a conductor that is rectangular in cross section, that is near a ground plane, and where both the conductor and the ground plane are embedded in a dielectric material may be approximated by the formula

$${Z}_{O} = \frac{60}{\sqrt{{e}_{r} ( 1 - exp ( - 1.55 {H}_{1} / H ) )}} Ln ( \frac{5.98 H}{.8 W + T} )$$

where:
Z_{O}=characteristic impedance in ohms,
H=height 1120 of the center of conductor plane 1102 above the ground plane 1104,
H₁=distance 1125 of the surface 1132 of the flexible circuit 420 above the ground plane 1104,
W=width 1206 of the conductor (parallel with the ground plane),
T=thickness 1202 of the conductor (perpendicular to the ground plane),
eᵣ=relative permittivity of the dielectric medium,
Ln denotes the natural logarithm, and
exp denotes the exponential function

As the Brooks article points out, such expressions are approximations and depend to a large degree upon the value of relative permittivity selected. In the case of the flexible circuits, the signal conductors 1002 and grounds 1005 are embedded in a media comprised of dielectric Kapton® and adhesive. Generally, the effect of the adhesive is to give an overall relative permittivity that is less than that of the dielectric alone. Thus, the actual effective relative permittivity will be from a combination of materials. According to DuPont literature the relative permittivity of Kapton® varies over a range of environmental and other conditions. A reasonable approximation for a medium which is primarily Kapton® and adhesives is a value of 3.0 to 3.4. It is further seen that the characteristic impedance can be “designed in” by adjusting the parameters H, H₁, W, and T.

A further design consideration is the width of the ground segments 1005 in comparison to the width W of the signal conductors 1002. Experience has shown the inventor that for the ground conductor to behave as a ground plane and for the above formula to give reasonable results, the width of the ground segments 1005 should be several times wider than W and at least four times H, the height of the conductor above the ground segment 1005. A final design consideration is that the spacing from a conductor to an adjacent conductor should be large to minimize cross talk to acceptable levels.

FIG. 12 is a partial cross section of flexible circuit 420 in the preferred embodiment that is under discussion showing a cross section of one signal conductor 1002, its corresponding ground segment 1005, and partial cross sections of its two neighboring ground segments 1005a. The cross section is taken in the narrow section 950 of flexible circuit 420, where the signal conductors are most closely spaced. The configuration is designed for an approximate characteristic impedance of 75 ohms, assuming a value of eᵣ of 3.2. The width 1206 and thickness 1202 of signal conductor 1002 are 1.5 mils and 1.2 mils respectively. The height of the center of signal conductor 1102 above the ground plane 1104 is 7.6 mils and includes of a 5-mil layer 1103 of Kapton® and two 1-mil layers of adhesive 1111. The widths 1210 of ground segments 1005 are each 40 mils. The non-conductive gap 1006 between adjacent ground segments 1005 has a dimension of 10 mils. Thus, the signal conductor 1002/ground segment 1005 pairs are located on 50 mil centers, and the center to center spacing between signal conductors is a factor of approximately nine times their width and a factor of approximately seven times the distance between the conductor 1002 and its ground 1005. Thus, the units are spaced sufficiently apart to keep cross talk to within acceptable levels.

Simulations and measurements performed by the supplier of the flexible circuits for the preferred embodiment verified that the desired characteristic impedance was achieved within acceptable tolerances.

Auxiliary flexible circuit 425 may be designed in a similar way. However, the utility signals carried by flexible circuit 425 are often low frequency or essentially “dc” and typically do not require controlled characteristic impedances and are not sensitive to cross talk.

Other embodiments having different configurations of flexible circuits 420 and assemblies 900 are possible. First, as mentioned previously, rather than separating the ground conductors 1005 in conductive layer 1104, a single ground plane could be used for several or all signal conductors 1002. Also, embodiments have been constructed where additional traces, used for grounds, have been included in the signal conductor layer 1102. For example, a ground carrying trace could be placed between every two signal traces 1002, thus placing a ground conductor on each side of each signal conductor. The ends of the additional ground traces could terminate at plated through holes 1010, which are connected to the grounds in layer 1104. This configuration could further decrease cross talk between adjacent signals. A further possibilility would be to include a ground trace between every pair of signal traces 1002 so that each signal trace 1002 has one ground trace adjacent to it. Yet another possibility would be to include some signal traces in both layers 1102 and 1104 and to include corresponding ground plane segments in both layers 1102 and 1104. In still other configurations, it could be feasible to include more or fewer layers of conductor, separated by dielectric layers, to convey signals and grounds.

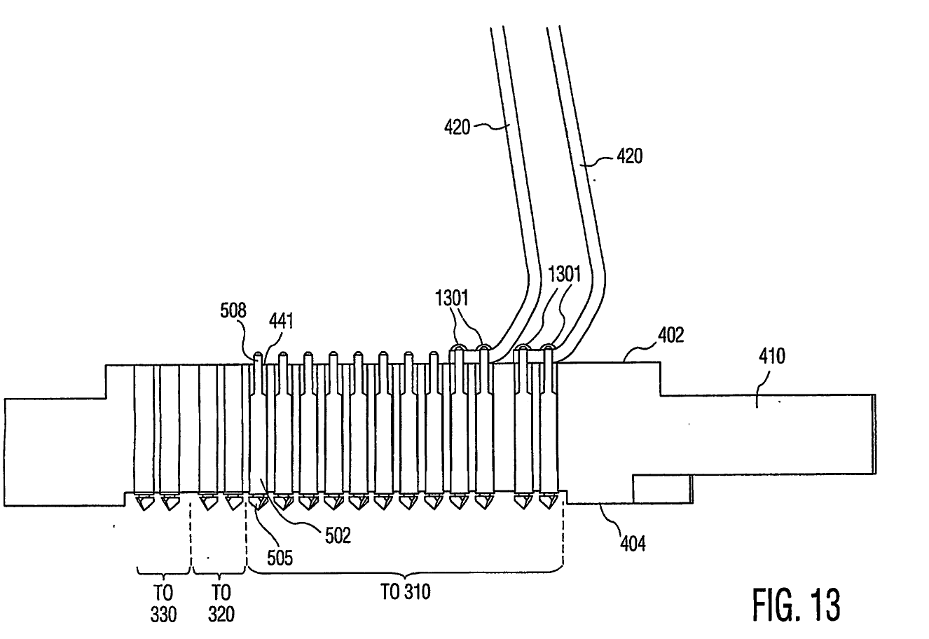

FIG. 13 shows an alternative means of connecting the flexible circuits 420 to spring-loaded contact pin receptacle posts 508. In the embodiment just discussed, a connector 440 having female receptacles 942 was used for this purpose. As an alternative, the plated through holes 1010 and 1020 at the PE end 930 of flexible circuit 420 may be placed directly over posts 508 and soldered in place, forming solder joints 1301. To do so the physical size, location, and spacing of plated through holes 1010 and 1020 may have to be appropriately designed.

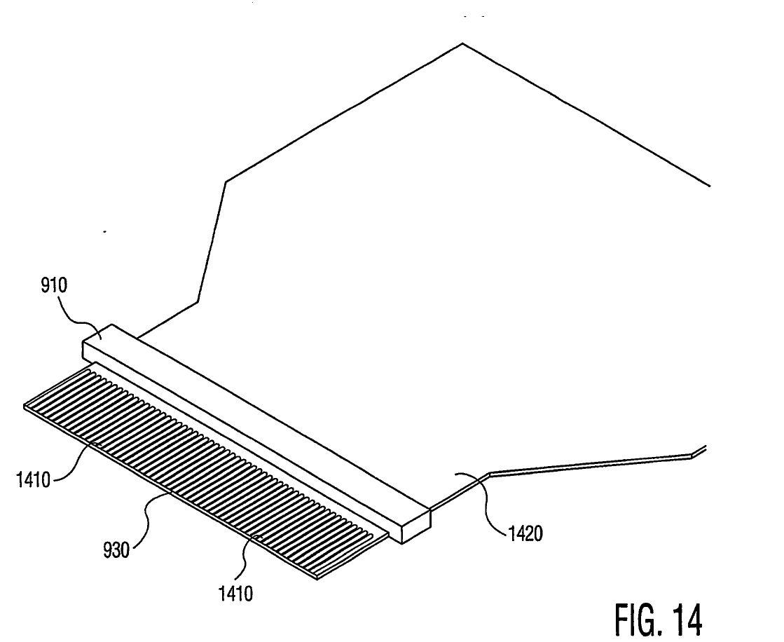

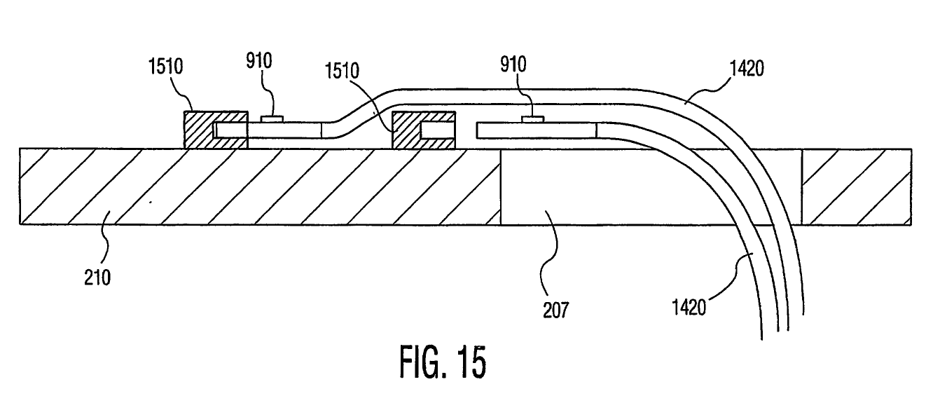

FIGS. 14 and 15 illustrate an alternative means to connect flexible circuits to a motherboard. In the embodiment previously discussed, a connector 430 having female receptacles 932 is used to connect the flexible circuit 420 to the pin electronics mother board 210. There are several other known methods of connecting flexible circuits to printed circuit boards that could be alternatively used. For example, FIG. 14 shows the PE end 930 of an alternative flexible circuit 1420, on which “edge connector fingers” 1410 have been formed. Forming such fingers 1410 is a standard operation in the manufacture of flexible circuits. Several manufacturers, such as Hirose Electric Co. Ltd. and Molex, supply zero insertion force or ZIF connectors, which can be mounted on printed circuit boards to receive, flexible circuit edge connector fingers. Stiffener 910 is attached to flexible circuit 1410 near the PE end 930 to provide some local rigidity. FIG. 15 is a cross sectional view illustrating a pin electronics motherboard 210 that has two ZIF connectors 1510 mounted on it that receive edge connector fingers 1410 on flexible circuits 1420. The ZIF connectors 1510 have open and closed positions. The edge connector fingers 1410 are first inserted into ZIF connector 1510 when it is in the open position with little or no resistive force. An actuator (not shown) is then operated and ZIF connector 1510 is driven to its closed position. As it closes, mating contact within connector 1510 wipe the fingers 1410 to make a good connection. Also, when in the closed position, flexible circuit 1420 is held firmly in place. The connection may be released by means of the actuator.

The PECM apparatus as described enables novel methods of manufacturing, maintaining, and in-the-field reconfiguring test heads, all of which provide cost and quality advantages.

First, PECMs may be separately manufactured as subassemblies and then installed in the test head as it is assembled. Fixtures and automation techniques can be employed to make the assembly process as economical as possible.

PECM subassemblies may be manufactured in a variety of configurations to meet different end-user scenarios. For end-users who need a minimum configuration of test pins and who are not likely to ever reconfigure or expand the test head, PECMs having only the necessary quantity of flexible circuits and spring-loaded contact pin assemblies can be utilized. However, in cases where later expansion is highly probable, PECMs having all flexible circuits and spring-loaded contact pin assemblies can be provided. When the system is expanded by adding pin electronics, the necessary flexible circuits are already present and need only to be plugged in. A middle of the road alternative is to use PECMs having all spring-loaded contact pin assemblies installed, but not the flexible circuits that won't be initially needed. These can be added at a later time when and if the system is expanded.

Second, the assembly of a test head is greatly simplified in that the hundreds or thousands of connections between the pin electronics and the test interface do not have to be individually wired. Rather a simple and straightforward method of assembly including the steps of installing pre-assembled PECMs, installing pin electronics motherboards or other modules, and plugging the PE ends of the flexible circuits into mating connectors on the pin electronics mother board. The use of coaxial cable for the connections is eliminated saving considerable costs and labor. Further the arrangement of the flexible circuits within the PECMs combined with the fact that 32 signal-ground connections are made simultaneously with easy to use connectors, assures that the connections will be made with a high degree of accuracy and quality. Also, each PECM may be tested as a separate module to assure its integrity. Thus, test head manufacturing labor is reduced and quality is improved.

Third, test heads may be easily reconfigured or upgraded in the field. Pin electronics can be added by adding the motherboards. The new motherboards can be simply wired to the interface by connecting them to flexible circuits within the PECMs. Also, pin electronics can be easily replaced by disconnecting the PECMs from the existing motherboards, removing the motherboards, installing new boards, and reconnecting the PECMs. Thus, the pin electronics can be upgraded to meet new technology requirements. As noted above there are several options including: replacing PECMs, using existing previously non-utilized flexible circuits which were installed at the time of original manufacture, and adding flexible circuits to the PECM which connect to previously non-utilized spring-loaded contact pin assemblies which were installed at the time of original manufacture. Generally it is not practical to add spring-loaded contact pin assemblies in the field. The use of PECMs avoids the necessity to return equipment to the factory and permits field changes to have factory accuracy and quality, thus providing considerable cost advantages.

Although illustrated and described herein with reference to certain specific embodiments, the present invention is nevertheless not intended to be limited to the details shown. Rather, various modifications may be made in the details within the scope and range of equivalence of the claims and without departing from the spirit of the invention.

What is claimed:

1. A connection module for use with a test head system, the test head system including a test head for testing devices, said connection module comprising:
a plurality of flexible circuits for transmitting and receiving signals between electronics in the test head and a device to be tested; and
connection points on a first end of each of said flexible circuits for connecting said flexible circuits to the electronics in the test head.

2. The connection module of claim 1 wherein each of said flexible circuits includes a plurality of conductive paths.

3. The connection module of claim 1 wherein each of said flexible circuits includes at least one signal conductive path and one ground conductive path.

4. The connection module of claim 1 wherein at least one of said flexible circuits includes a plurality of layers.

5. The connection module of claim 4 wherein said at least one of said flexible circuits includes three insulative layers and two conductive layers arranged such that each of said two conductive layers is surrounded by a respective two of said three insulative layers.

6. The connection module of claim 5 wherein one of said conductive layers is a signal layer, and the other of said conductive layers is a ground layer.

7. The connection module of claim 6 wherein said signal layer and said ground layer each include a plurality of conductive paths.

8. The connection module of claim 6 wherein said signal layer includes a plurality of conductive paths, and said ground layer includes a single conductive plane.

9. The connection module of claim 5 wherein at least one of said conductive layers includes signal conductors and ground conductors.

10. The connection module of claim 3 wherein said at least one signal conductive path includes a strip line.

11. The connection module of claim 1 wherein the width of at least one of said plurality of flexible circuits varies along the length of said at least one flexible circuit.

12. The connection module of claim 1 wherein each of said plurality of flexible circuits includes a pin electronics end for connecting to the electronics in the test head and an interface end for providing interconnection with the device to be tested.

13. The connection module of claim 12 wherein said interface end includes a plurality of conductive plated through holes for mating with respective conductive posts, the conductive posts providing interconnection with the device to be tested.

14. The connection module of claim 12 wherein said interface end includes a plurality of conductive posts for mating with respective conductive plated through holes, the conductive plated through holes providing interconnection with the device to be tested.

15. The connection module of claim 13 wherein each of said conductive posts is connected to a spring-loaded contact pin receptacle for receiving a spring-loaded contact pin, said spring-loaded contact pin providing interconnection with the device to be tested.

16. The connection module of claim 12 wherein each of said plurality of flexible circuits includes a interface connector block at the interface end, said interface connector block defining a plurality of female receptacles for mating with a respective plurality of conductive posts, the conductive posts providing interconnection with the device to be tested.

17. The connection module of claim 12 wherein each of said plurality of flexible circuits includes a interface connector block at the interface end, said interface connector block including a plurality of conductive posts for mating with a respective plurality of female receptacles, the female receptacles providing interconnection with the device to be tested.

18. The connection module of claim 16 wherein each of said conductive posts is connected to a spring-loaded contact pin receptacle for receiving a spring-loaded contact pin, said spring-loaded contact pin providing interconnection with the device to be tested.

19. The connection module of claim 12 wherein each of said plurality of flexible circuits includes a pin electronics connector block at the pin electronics end, said pin electronics connector block defining a plurality of female receptacles for mating with a respective plurality of conductive posts, the conductive posts providing interconnection with the electronics in the test head.

20. The connection module of claim 12 wherein each of said plurality of flexible circuits includes a pin electronics connector block at the pin electronics end, said pin electronics connector block including a plurality of conductive posts for mating with a respective plurality of female receptacles, the female receptacles providing interconnection with the electronics in the test head.

21. The connection module of claim 12 wherein the pin electronics end includes a plurality of conductive tabs configured to mate with at least one zero insertion force connector, said zero insertion force connector providing interconnection between the plurality of conductive tabs and electronics in the test head.

22. The connection module of claim 12 wherein the pin electronics end includes at least one zero insertion force connector for mating with a plurality of conductive tabs, said conductive tabs providing interconnection between the zero insertion force connector and electronics in the test head.

23. The connection module of claim 1 wherein at least one of said flexible circuits includes auxilliary electrical circuits for the test head system.

24. The connection module of claim 1 wherein said flexible circuits include a material selected from the group consisting of fluoropolymer film, aramid fiber-based paper, aramid fiber-based cloth, formable composite, flexible epoxy based composite, and thermoplastic film.

25. The connection module of claim 1 wherein said flexible circuits comprise a patterned arrangement of printed wiring and a flexible base material.

26. An interface for providing interconnection between a test head and a device to be tested, said interface comprising:
a plurality of connection modules, each of said connection modules including a plurality of flexible circuits for transmitting and receiving signals between electronics in the test head and the device to be tested; and
a device interface providing interconnection between at least one of said plurality of connection modules and the device to be tested.

27. The interface of claim 26 wherein said plurality of connection modules are radially arranged and define a center hole in said interface for aligning with a viewing hole of the test head.

28. The interface of claim 26 wherein the width of at least one of said plurality of flexible circuits varies along the length of said at least one flexible circuit.

29. The interface of claim 26 wherein said flexible circuits include a material selected from the group consisting of fluoropolymer film, aramid fiber-based paper, aramid fiber-based cloth, formable composite, flexible epoxy based composite, and thermoplastic film.

30. The interface of claim 26 wherein said flexible circuits comprise a patterned arrangement of printed wiring and a flexible base material.

31. A test head system comprising:
a test head including a plurality of electronic circuits; and
an interface for providing interconnection between said test head and a device to be tested, said interface including a plurality of flexible circuits for transmitting and receiving signals between said plurality of electronic circuits and the device to be tested.

32. The test head system of claim 31 wherein the width of at least one of said plurality of flexible circuits varies along the length of said at least one flexible circuit.

33. The test head system of claim 31 wherein said flexible circuits include a material selected from the group consisting of fluoropolymer film, aramid fiber-based paper, aramid fiber-based cloth, formable composite, flexible epoxy based composite, and thermoplastic film.

34. The test head system of claim 31 wherein said flexible circuits comprise a patterned arrangement of printed wiring and a flexible base material.

35. A method of connecting a test head to a device to be tested comprising the steps of:
providing at least one connection module, said connection module including,
a plurality of flexible circuits for transmitting and receiving signals between electronics in the test head and the device to be tested; and
connecting said connection module between electronics in the test head and the device to be tested.

36. A method of modifying a test head system comprising the steps of:
removing a first flexible circuit from said test head system, the first flexible circuit having a first configuration for exchanging signals between electronics in a test head and a device to be tested, and
replacing the first flexible circuit with a second flexible circuit having a second configuration, the second flexible circuit for exchanging signals between the electronics in the test head and a device to be tested, the first configuration being different from the second configuration.

37. A method of modifying a test head system comprising the steps of:
removing a first connection module from the test head system, the first connection module having a first configuration and including a plurality of flexible circuits for exchanging signals between electronics in a test head and a device to be tested; and
replacing the first connection module with a second connection module having a second configuration, the second connection module including a plurality of flexible circuits for exchanging signals between the electronics in the test head and a device to be tested, the first configuration being different from the second configuration.

38. A method of modifying a test head system comprising the steps of:
providing a flexible circuit configured for transmitting and receiving signals between electronics in a test head and a device to be tested; and
adding the flexible circuit to the test head system.

39. A method of assembling a test head system, the test head system including a test head for testing devices, the method comprising the steps of:
providing a plurality of connection modules, each of said connection modules including a plurality of flexible circuits for transmitting and receiving signals between electronics in the test head and the device to be tested; and
assembling an interface for providing interconnection between the test head and the device to be tested, said step of assembling including arranging said connection modules in a predetermined configuration.
